(19) United States
(12) Patent Application Publication
(10) Pub. No.: US 2009/0305438 A1
(43) Pub. Date: Dec. 10, 2009

(54) Trench isolation method of semiconductor device using chemical mechanical polishing process

(76) Inventors: Il-young Yoon, Yongin-si (KR); Tae-hoon Lee, Suwon-si (KR); Jae-ouk Choo, Yongin-si (KR)

Correspondence Address: LEE & MORSE, P.C., 3141 FAIRVIEW PARK DRIVE, SUITE 500, FALLS CHURCH, VA, 22042, US

(21) Appl. No.: 12/457,040

(22) Filed: May 29, 2009

(30) Foreign Application Priority Data
Jun. 9, 2008 (KR) 10-2008-0053806

(51) Int. Cl. H01L 21/306; H01L 21/762; H01L 21/66

(52) U.S. Cl. 438/7; 438/424; 438/693; 257/E21.546; 257/E21.528; 257/E21.23

(57) ABSTRACT

A trench isolation method of a semiconductor device includes forming polishing prevention film patterns on a semiconductor substrate, etching the semiconductor device by using the polishing prevention film patterns as masks and forming trenches, and forming conformal insulation films on the semiconductor substrate and the polishing prevention film patterns by burying the trenches. The conformal insulation films are first polished using a first polishing pad by using a slurry including an abrasive having a polishing selection ratio with respect to the polishing prevention film patterns. The first polished conformal insulation films are second polished using a second polishing pad including an abrasive and by using the polishing prevention film patterns as polishing prevention films.

### BACKGROUND

1. Field

Embodiments relate to a method of manufacturing a semiconductor device, and a trench isolation method of a semiconductor device using a chemical mechanical polishing (CMP) process.

2. Description of the Related Art

A trench isolation process is generally performed in order to form unit elements (devices) on a semiconductor substrate, e.g., a silicon substrate. The trench isolation process forms a plurality of trenches on the semiconductor substrate and an insulation film on the front surface of the semiconductor substrate by burying the insulation film, e.g., a silicon oxide film, in the trenches, then polishes the insulation film chemically and mechanically, while the insulation film remains buried in the trenches.

Because very narrow trenches, however, result from a highly-integrated semiconductor device, it is difficult to bury the insulation film in the trenches. Therefore, various methods of burying the insulation film in narrow trenches have been developed. Additionally, as semiconductor devices are produced in more varieties, more varieties of semiconductor substrate, e.g., substrate having a high pattern density, or a low density, wide trench parts or narrow trench parts, ensued. When a semiconductor substrate has a different pattern density and trenches having different widths, the chemical and mechanical polishing process used for the trench isolation does not have a large margin. In more detail, when the chemical and mechanical polishing process is used to polish an insulation film formed on a semiconductor substrate having trenches or a pattern, there is a very likelihood of over-polishing or under-polishing specific parts of the substrate. In particular, if the insulation film formed on the semiconductor substrate is sunken in, i.e., dishing occurs, then, the reliability of the semiconductor device may be greatly reduced.

Furthermore, as described above, the factors such as a high degree of integration and variety in types of semiconductor devices cause a large reduction in a process margin of the CMP process so that it is difficult to perform the CMP process.

### SUMMARY

Embodiments are therefore directed to a trench isolation method of a semiconductor device capable of polishing a semiconductor substrate chemically and mechanically, which substantially overcomes one or more of the disadvantages of the related art.

It is therefore a feature of an embodiment to provide a trench isolation method of a semiconductor device capable of increasing a chemical mechanical polishing (CMP) process margin when a process of trench isolation is performed.

It is therefore another feature of an embodiment to provide a trench isolation method of a semiconductor device capable of increasing the reliability of the semiconductor device.

At least one of the above features and other advantages may be realized by providing a trench isolation method of a semiconductor device including forming polishing prevention film patterns on a semiconductor substrate, etching the semiconductor device by using the polishing prevention film patterns as masks and forming trenches, and forming conformal insulation films on the semiconductor substrate and the polishing prevention film patterns by burying the trenches. The conformal insulation films are first polished using a first polishing pad and by using a slurry including an abrasive having a polishing selection ratio with respect to the polishing prevention film patterns. The first polished conformal insulation films are second polished using a second polishing pad including an abrasive and by using the polishing prevention film patterns as polishing prevention films.

The polishing prevention film patterns may be silicon nitride films or silicon oxide nitride films.

The conformal insulation films may be boronphosphosilicate glass (BPSG) films, phosphosilicate glass (PSG) films, high density plasma (HDP) oxide films, tetra ethyl ortho silicate (TEOS) films, undoped silica glass (USG) films, or high aspect ratio process (HARP) films, e.g., silicon oxide films. The conformal insulation films 54a and 54b may preferably be the HARP films.

A ceria slurry may be used to first polish the conformal insulation films. The ceria slurry that may be used to first polish the conformal insulation films has pH of about 5 to about 9. Before first polishing the conformal insulation films using the ceria slurry, the conformal insulation films may be preliminarily polished by the first polishing pad using a silica slurry.

When the conformal insulation films are first polished, an end point detection method may be used to maintain a part of the conformal insulation films that has an original thickness on the polishing prevention film patterns. The abrasive used to second polish the conformal insulation films may be ceria.

At least one of the above features and other advantages may be realized by providing a trench isolation method of a semiconductor device including forming polishing prevention film patterns on a semiconductor substrate, etching the semiconductor device by using the polishing prevention film patterns as masks and forming trenches, forming insulation films on the semiconductor substrate and the polishing prevention film patterns by burying the trenches, wherein the insulation films have a step between the surface of a part that is buried in the trenches and the surface of a part formed on the semiconductor substrate and the polishing prevention film patterns, first polishing and planarizing the insulation films having the step using a first polishing pad, using a slurry including an abrasive having a polishing selection ratio with respect to the polishing prevention film patterns, and second polishing the first polished insulation film patterns using a second polishing pad including an abrasive and by using the polishing prevention film patterns as polishing prevention films.

The trenches may include a narrow first trench and a second trench that is wider than the first trench. The polishing prevention film patterns may include a narrow first polishing prevention film pattern and a second polishing prevention film pattern that is wider than the first polishing prevention film pattern.

The conformal insulation films may be boronphosphosilicate glass (BPSG) films, phosphosilicate glass (PSG) films, high density plasma (HDP) oxide films, tetra ethyl ortho silicate (TEOS) films, undoped silica glass (USG) films, or high aspect ratio process (HARP) films, e.g., silicon oxide films. The conformal insulation films 54a and 54b may preferably be the HARP films.

A ceria slurry may be used to first polish the insulation films, and ceria may be used to second polish the insulation films.

Prior to first polishing of the insulation films using the ceria slurry, the insulation films may be preliminarily polished using the first polishing pad by using a silica slurry. When the insulation films are first polished, an end point detection method may be used to maintain a part of the insulation films that has an original thickness on the polishing prevention film patterns.

At least one of the above features and other advantages may be realized by providing a trench isolation method including forming a first part including first polishing prevention film patterns having a high density and a second part including second polishing prevention film patterns having a density lower than that of the first polishing prevention film patterns on a semiconductor substrate, forming a narrow first trench between the first polishing prevention film patterns on the semiconductor substrate, forming a second trench that is wider than the first trench between the second polishing prevention film patterns on the semiconductor substrate, forming insulation films having a step between the surface of a part that is buried in the second trench and the surface of a part formed on the semiconductor substrate, the first trench, and the first polishing prevention film pattern by burying the first and second trenches, first polishing and planarizing the insulation films having the step using a first polishing pad by using a slurry including an abrasive having a polishing selection ratio with respect to the first and second polishing prevention film patterns, and second polishing the first polished insulation films using a second polishing pad including an abrasive and by using the first and second polishing prevention film patterns as polishing prevention films.

When the insulation films are first polished, an end point detection method may be used to maintain a part of the insulation films that has an original thickness on the first polishing prevention film pattern. The first and second trenches may be formed by etching the semiconductor substrate by using the first and second polishing prevention film patterns, respectively, as masks.

The first and second polishing prevention films patterns are silicon nitride films or silicon oxide nitride films, and the insulation films may be boronphosphosilicate glass (BPSG) films, phosphosilicate glass (PSG) films, high density plasma (HDP) oxide films, tetra ethyl ortho silicate (TEOS) films, undoped silica glass (USG) films, or high aspect ratio process (HARP) films, and a ceria slurry is used to first polish the insulation films, and ceria is used to second polish the insulation films.

Prior to first polishing of the insulation films using the ceria slurry, the insulation films are preliminarily polished using the first polishing pad by using a silica slurry.

### BRIEF DESCRIPTION OF THE DRAWINGS

The above and other features and advantages will become more apparent to those of ordinary skill in the art by describing in detail exemplary embodiments with reference to the attached drawings, in which:

FIG. 1 illustrates a chemical and mechanical polishing (CMP) device used for an embodiment;

FIG. 2 illustrates one of first through third plates of the CMP device shown in FIG. 1;

FIG. 3 illustrates a cross-sectional view of a semiconductor device for which a trench isolation process is performed according to an embodiment;

FIGS. 4A, 4B, 5A, and 5B illustrate perspective views of a pattern density reduction rate of polishing prevention film patterns in a highly integrated semiconductor device processed according to an embodiment;

FIGS. 6A, 6B, 7A, and 7B illustrate plan views of FIGS. 4A, 4B, 5A, and 5B, respectively;

FIGS. 8 and 9 illustrate cross-sectional views of a comparative CMP process;

FIGS. 10 through 12 illustrate cross sectional views of a trench isolation method of a semiconductor device using the CMP according to an embodiment;

FIG. 12 illustrates a cross-sectional view of a combination of FIGS. 10 and 11;

FIG. 13 illustrates a graph of end point detection time with respect to semiconductor substrates when insulation films are first polished as shown in FIG. 10;

FIG. 14 illustrates a graph of a current intensity of a motor rotating a platen to measure the end point detection time of FIG. 13;

FIG. 15 illustrates a graph of a dishing thickness when insulation films are first and second polished as shown in FIGS. 10 and 11;

FIG. 16 illustrates a graph of a thickness distribution of insulation films on polishing prevention film patterns after the insulation films are first polished as shown in FIG. 10; and

FIG. 17 illustrates a graph of the thickness distribution of the insulation films that are buried in trenches when the insulation films are first and second polished as shown in FIGS. 10 and 11.

### DETAILED DESCRIPTION

Korean Patent Application No. 10-2008-0053806, filed on Jun. 9, 2008, in the Korean Intellectual Property Office, and entitled: “Trench Isolation Method of Semiconductor Device Using Chemical Mechanical Polishing Process,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

Hereinafter, an expression “polishing” means chemical and mechanical polishing (CMP). The CMP means planarization of the surface of a semiconductor substrate (a semiconductor wafer), e.g., a silicon wafer, by combining a mechanical polishing effect obtained from a polishing agent and a chemical reaction effect obtained from an acid or a base solution.

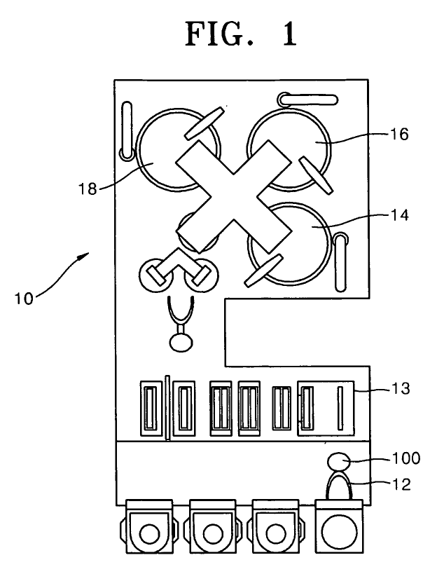

FIG. 1 illustrates a CMP device 10 used for an embodiment. Referring to FIG. 1, a robot 12 may transfer a wafer (a semiconductor substrate, or substrate) 100 to the CMP device 10. A transfer device 13 may carry the wafer 100 to a first plate 14. The first plate 14 may be supplied with an abrasive, e.g., a slurry (hereinafter, “silica slurry”) including a silica abrasive, or a slurry (hereinafter, “ceria slurry”) including a ceria abrasive and a surface active agent, to perform a CMP process.

The first plate 14 may transfer the wafer 100 to a second plate 16. The second plate 16 may include a polishing pad with an abrasive, e.g., a ceria abrasive, and may be supplied with the ceria slurry including the surface active agent. The second plate 16 may second polish the wafer 100.

A third plate 18 may be supplied with the ceria slurry including the ceria abrasive and the surface active agent. The third plate 18 may third polish the wafer 100. The surface active agent used for the present embodiment may be, e.g., carboxylic acid or a salt thereof, sulfuric ester or a salt thereof, sulfonic acid or a salt thereof, phosphoric ester or a salt thereof, or amine or a salt thereof.

The first, second and third plates 14, 16, and 18 may each include a polishing pad. The second plate 16 may include an abrasive, e.g., a ceria abrasive, which will be described later. The polishing pad including the abrasive is referred to as a fixed abrasive (FA) polishing pad. The CMP that uses the FA polishing pad is referred to as FACMP.

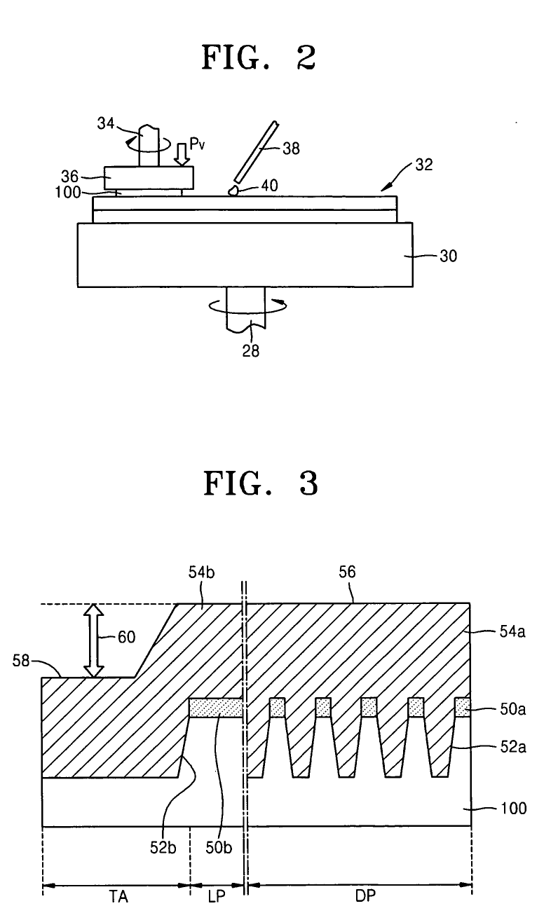

FIG. 2 illustrates one of the first through third plates 14, 16, and 18 of the CMP device 10 illustrated in FIG. 1.

Referring to FIG. 2, a platen 30 may be in a shape of a disk and may rotate in a direction of a rotation axis 28, e.g., counter clockwise. A polishing pad 32 may be on the platen 30 and may rotate according to the rotation of the platen 30, e.g., clockwise. A spindle 34 may be on the polishing pad 32.

The spindle 34 may rotate in the opposite direction that the platen 30 rotates. A carrier 36 may be fixed to the bottom of the spindle 34, and the substrate (wafer) 100 may be in the bottom of the carrier 36. The surface of the substrate 100 may be pressed to the polishing pad 32 by pressure Pv applied to the spindle 34. Polishing may proceed by the rotations of the platen 30 and the spindle 34.

A slurry supply device 38 may be disposed on the polishing pad 32. The slurry supply device 38 may supply a slurry 40 for the polishing pad 32. The slurry 40 may be supplied between the surface of the substrate 100 and the polishing pad 32 to control a polishing speed. The slurry 40 may include an abrasive as described above, however, if the polishing pad 32 includes the abrasive, then the slurry 40 may not include the abrasive.

FIG. 3 illustrates a cross-sectional view of a semiconductor device for which a trench isolation process is performed according to an embodiment. Referring to FIG. 3, first and second polishing prevention film patterns 50a and 50b may be formed in an active area of the semiconductor substrate (wafer) 100, e.g., a silicon substrate. The first and second polishing prevention film patterns 50a and 50b may be formed of, e.g., a silicon nitride film or a silicon acid nitride film. The semiconductor substrate 100 may be divided into a first part DP including the first polishing prevention film patterns 50a having a high density and a second part LP including the second polishing prevention film patterns 50b having a density lower than the first part DP. For descriptive convenience, the second part LP is illustrated to include a single second polishing prevention film pattern 50b.

The first and second polishing prevention film patterns 50a and 50b may be used as masks to etch the semiconductor substrate 100 and to form first and second trenches 52a and 52b. The first trenches 52a may have a narrow width and may be formed between the first polishing prevention film patterns 50a on the semiconductor substrate 100. The second trench 52b may have a width wider than that of the first trenches 52a, and may be formed between the second polishing prevention film patterns 50b, i.e., in one side of the second polishing prevention film patterns 50a, on the semiconductor substrate 100. The second trench 52b may be formed in a part TA of the semiconductor substrate 100.

Insulation films 54a and 54b may be formed on the semiconductor substrate 100 and on the first and second polishing prevention film patterns 50a and 50b by burying the first and second trenches 52a and 52b. The insulation films 54a and 54b may be conformal insulation films, having good trench burying characteristics. The conformal insulation films 54a and 54b may be formed in accordance with the bottom structure of the semiconductor substrate 100, and thus may be able to easily bury the narrow first trenches 52a and the wide second trench 52b.

The conformal insulation films 54a and 54b may be, e.g., boronphosphosilicate glass (BPSG) films, phosphosilicate glass (PSG) films, high density plasma (HDP) oxide films, tetra ethyl ortho silicate (TEOS) films, undoped silica glass (USG) films, or high aspect ratio process (HARP) films, e.g., silicon oxide films. The conformal insulation films 54a and 54b may preferably be the HARP films. The HARP films may be formed by depositing porous undoped silicate glass using O₃-TEOS, heat-treating the deposited porous undoped silicate glass at a high temperature, and flowing the oxide into trenches.

According to the formation of the conformal insulation films 54a and 54b, a surface difference between surface 56 of the conformal insulation films 54a and 54b and surface 58 of the part TA, in which the wide second trench 52b is formed, may cause a step 60. When the CMP device 10 is used to polish the conformal insulation films 54a and 54b by using the first and second polishing prevention film patterns 50a and 50b as the polishing prevention films, and to perform the trench isolation process, a polishing process margin may be greatly reduced, which may reduce the reliability of the high integration semiconductor device. This will be described in more detail later.

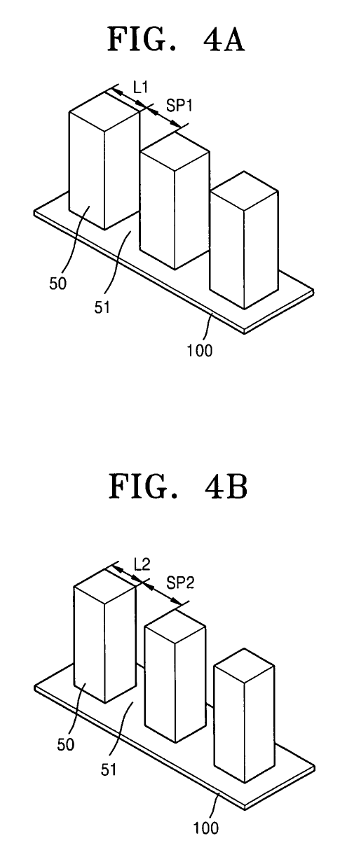

Another reason for the reduction of a CMP process margin when the CMP device 10 is used to perform the trench isolation process will now be described in detail with respect to FIGS. 4 through 7.

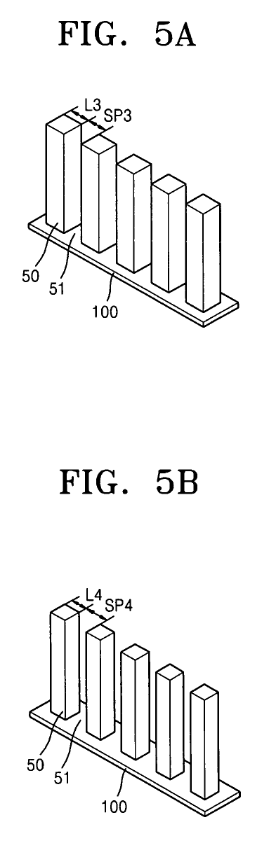

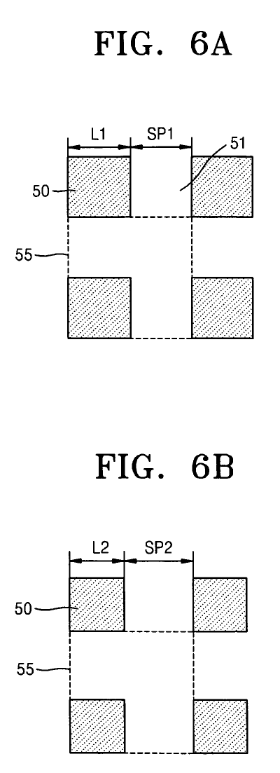

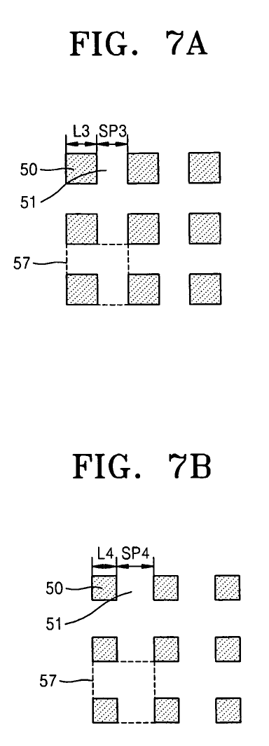

FIGS. 4A, 4B, 5A, and 5B illustrate perspective views explaining a pattern density reduction rate of polishing prevention film patterns 50 in a highly integrated semiconductor device applied to an embodiment. FIGS. 6A, 6B, 7A, and 7B illustrate plan views of FIGS. 4A, 4B, 5A, and 5B, respectively.

The polishing prevention film patterns 50 may function as polishing prevention films of the insulation films 54a and 54b when the trench isolation process is performed. Referring to FIGS. 4 through 7, the polishing prevention film patterns 50 includes the polishing prevention film patterns 50a and 50b. FIGS. 4 through 7 illustrate the reduction in the pattern density as a semiconductor device is highly integrated.

In FIGS. 4A, 5A, 6A, and 7A, a plurality of the polishing prevention film patterns 50 may be formed on the semiconductor substrate 100. In FIGS. 4A and 6A, each polishing prevention film pattern 50 has a line width of L1 and spaces 51 having width SP1 between adjacent polishing prevention film patterns 50. In FIGS. 5A and 7A, each polishing prevention film pattern 50 has a line width of L3 and spaces 51 having width SP3 between the adjacent polishing prevention film pattern 50.

In FIGS. 4B, 5B, 6B, and 7B, the width of each polishing prevention film pattern 50 is reduced to more highly integrate the polishing prevention film pattern 50 relative to those of FIGS. 4A, 5A, 6A, and 7A. In more detail, each polishing prevention film pattern 50 in FIGS. 4B and 6B has a line width of L2 that is shorter than the line width of L1 and the spaces 51 having a width SP2 between the adjacent polishing prevention film pattern 50 that is wider than the width of SP1. Similarly, in FIGS. 5B and 7B, each polishing prevention film pattern 50 has a line width of L4 that is shorter than the line width of L3 and the spaces 51 having a width SP4 between the adjacent polishing prevention film patterns 50 that is wider than the width of SP3.

For example, if L1 and SP1 for each polishing prevention film pattern 50 are 140 nm in FIGS. 4A and 6B and are reduced by 10 nm in FIGS. 4B and 6B, the L2 and SP2 are 130 nm and 150 nm, respectively. In this case, 25% pattern density of FIGS. 4A and 6A is reduced to about 21.6% in FIGS. 4B and 6B, thereby achieving about 3.4% pattern density reduction. The reduction is illustrated in view of a unit area indicated as a dotted line 55 in FIGS. 6A and 6B.

If L3 and SP3 for each polishing prevention film pattern 50 are 70 nm in FIGS. 5A and 7A and are reduced by 10 nm in FIGS. 5B and 7B, the L4 and SP4 are 60 nm and 80 nm, respectively. In this case, 25% pattern density of FIGS. 5A and 7A is reduced to about 18.4% in FIGS. 5B and 7B, thereby achieving about 6.6% pattern density reduction. The reduction is illustrated in view of a unit area indicated as a dotted line 57 in FIGS. 7A and 7B. As described, the pattern density reduction rate increases more in the case where the pattern size is smaller due to high integration of the semiconductor device than the case where the pattern size is larger, though the pattern size is reduced by the same size.

Because the pattern density reduction rate of the polishing prevention film patterns 50 increases as the semiconductor device is highly integrated, when the CMP device 10 is used to perform the trench isolation process, the CMP process margin may be greatly reduced.

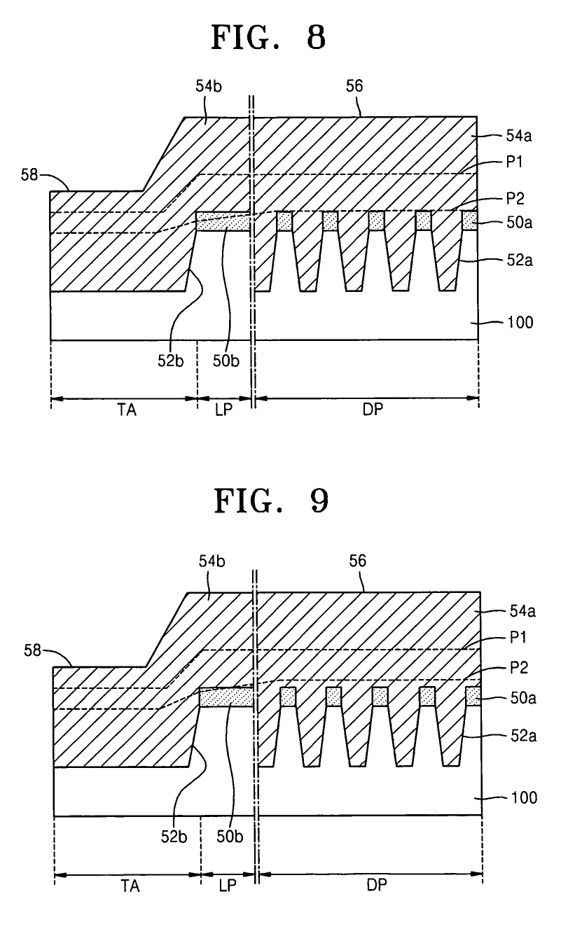

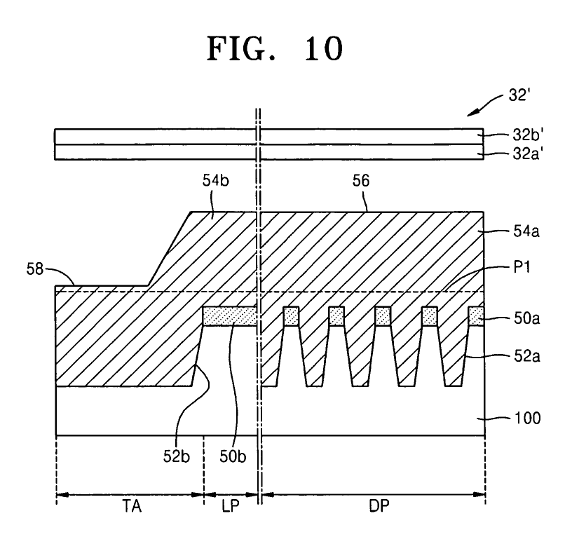

FIGS. 8 and 9 illustrate cross-sectional views explaining a comparative CMP process. The reference numerals from FIG. 3 are used in FIGS. 8 and 9 to denote same elements. Referring to FIGS. 8 and 9, a polishing end point line P1 is obtained after first CMP using a slurry, e.g., a silica slurry, which does not have a polishing selection rate of the insulation films 54a and 54b with respect to the first and second polishing prevention film patterns 50a and 50b, is performed. In the polishing end point line P1, the first and second parts DP and LP and the wide trench area TA have a step due to a pattern density difference. A polishing end point line P2 is obtained after second CMP using a FA polishing pad is performed.

Referring to FIG. 8, insulation films 54a and 54b are second polished after being over-polished during the first polishing. The step caused by the difference in the pattern density results in over-polishing of the insulation films 54b in the wide trench part TA after the insulation films 54b are second polished, while the polishing prevention film pattern 50b of the second part LP are polished. Referring to FIG. 9, the first part DP is second polished after the first part DP, including the first polishing prevention film patterns 50a having a high density, is under-polished during the first polishing. Since the insulation films 54a and 54b of the first part DP are not completely polished even after being second polished, it may be difficult to entirely remove the polishing prevention film patterns 50a and 50b.

In contrast to the CMP described in FIGS. 8 and 9, FIGS. 10 through 12 illustrate cross sectional views explaining a trench isolation method of a semiconductor device by using the CMP according to an embodiment.

Referring to FIG. 10, the first and second polishing prevention film patterns 50a and 50b may be formed on the semiconductor substrate 100, as described in FIG. 3. The first and second polishing prevention film patterns 50a and 50b may be formed of a silicon nitride film SiN, or a silicon acid nitride film SiON having a polishing selection ratio with respect to silicon oxide films. The first and second polishing prevention film patterns 50a and 50b may have the thickness of about 300 Å to about 600 Å. The first and second polishing prevention film patterns 50a and 50b may be used as masks to etch the semiconductor substrate 100 and may form the first and second trenches 52a and 52b. The first and second trenches 52a and 52b may have the thickness of about 2,000 Å to about 3,000 Å.

The insulation films 54a and 54b may be formed on the semiconductor substrate 100 and on the first and second polishing prevention film patterns 50a and 50b by burying the first and second trenches 52a and 52b. The insulation films 54a and 54b may be formed to fully cover the semiconductor substrate 100 and the first and second polishing prevention film patterns 50a and 50b by burying the first and second trenches 52a and 52b. Since the insulation films 54a and 54b may be conformal insulation films, a step may be generated between the surface of a part buried in the first and second trenches 52a and 52b and the surface of a part formed on the semiconductor substrate and the first and second polishing prevention film patterns 50a and 50b.

The semiconductor substrate 100 may be mounted in the carrier 36 of the first plate 14 of the CMP device 10 (shown in FIGS. 1 and 2). The insulation films 54a and 54b on the semiconductor substrate 100 may face the first polishing pad 32′. The first polishing pad 32′ may include a base 32b′ and an abrasive layer 32a′ on the base 32b′.

A slurry supply device (not shown) may supply a slurry including an abrasive to the first polishing pad 32′, which first performs CMP with respect to the insulation films 54a and 54b. The first polishing may be performed by using an abrasive having a high polishing selection ratio of the insulation films 54a and 54b with respect to the first and second polishing prevention film patterns 50a and 50b. The first polishing may use a ceria slurry as the abrasive. The ceria slurry may have pH of about 5 to about 9 when the insulation films 54a and 54b are first polished. In the first polishing, the carrier 36 may apply a pressure of about 1 psi to about 4 psi to the first polishing pad 32′.

In the present embodiment, since the first polishing uses the abrasive having a high polishing selection ratio of the insulation films 54a and 54b with respect to the polishing prevention film patterns 50a and 50b, the polishing end point line P1 does not have a step and is disposed at a predetermined height from a wide trench part, a wide polishing prevention film patterns 50b, and the narrow polishing prevention film patterns 50a. More specifically, the first polishing planarizes the insulation films 54a and 54b. In the first polishing, the insulation films 54a and 54b remaining on the polishing prevention film patterns 50a and 50b may have the thickness of about 0 Å to about 300 Å, but preferably about 200 Å.

When the insulation films 54a and 54b are first polished, an end point detection method may be used to accurately maintain a part of the insulation films 54a and 54b that has an original thickness on the polishing prevention film patterns 50a and 50b. This may be important in the case that the end point detection method is performed by measuring a current intensity of a motor that rotates the platen 30. When a part of the insulation films 54a and 54b that has the original thickness is accurately maintained on the polishing prevention film patterns 50a and 50b, a polishing margin may be greatly increased.

Prior to the insulation films 54a and 54b being first polished, the insulation films 54a and 54b may be preliminarily polished using the silica slurry and the first polishing pad 32′ in the first plate 14.

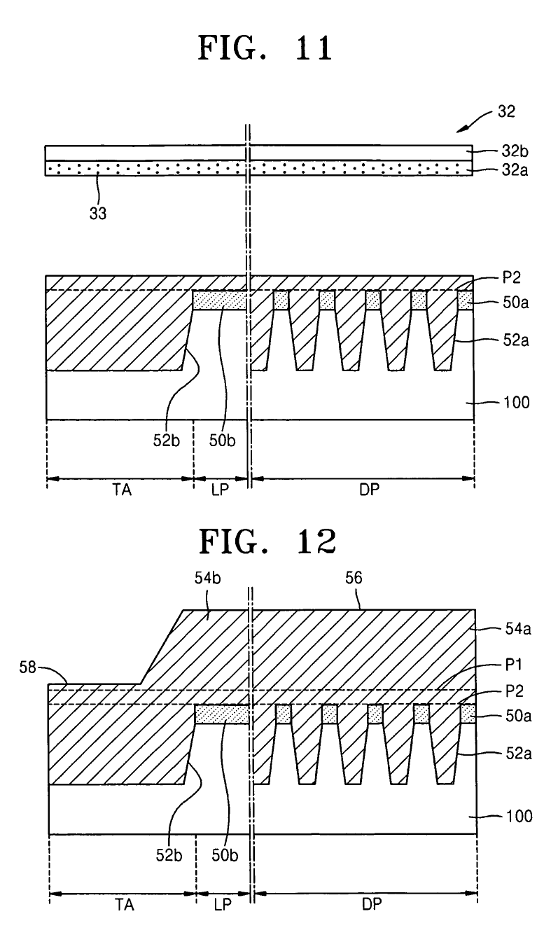

Referring to FIG. 11, the first polished semiconductor substrate 100 may be mounted on the carrier 36 of the second plate 16 of the CMP device 10 (shown in FIGS. 1 and 2). A second polishing pad 32 including an abrasive 33 may be used to second polish the first polished insulation films 54a and 54b. In the second polishing, the carrier 36 may apply a pressure of about 1 psi to about 4 psi to the second polishing pad 32.

The second polishing pad 32 may comprise a base 32b and an abrasive layer 32a that is on the base 32b. The abrasive layer may include an abrasive 33. The base 32b may be, e.g., polyurethane, polyester, polyether, epoxy, polyimide, polycarbonate, polyethylene, polypropylene, latex, nitrile rubber, isoprene rubber, etc., preferably polyurethane.

The second polishing may use the ceria abrasive. In the second polishing, the polishing prevention film patterns 50a and 50b may be used as polishing prevention films. In the present embodiment, the polishing end point line P2 may be formed in accordance with the surface of the polishing prevention film patterns 50a and 50b. Therefore, a wide trench part and the wide polishing prevention film patterns 50b may not be over-polished, or the narrow polishing prevention film patterns 50a may not be removed in the present embodiment.

FIG. 12 illustrates a cross-sectional view of a combination of FIGS. 10 and 11. As described above, the polishing end point line P1 may be planarized at a predetermined height on the first and second polishing prevention film patterns 50a and 50b during the first polishing. The polishing end point line P2 may be formed to be consistent with the surface of the first and second polishing prevention film patterns 50a and 50b during the second polishing.

The second polished semiconductor substrate (wafer) 100 may be mounted on the carrier 36 of the third plate 18 of the CMP device 10 (shown in FIGS. 1 and 2). The third polishing pad 32 may be used to third polish the second polished insulation films 54a and 54b to more accurately remove the insulation films 54a and 54b. The third polishing pad 32 may be the same as the first polishing pad 32 and may use a ceria slurry as an abrasive.

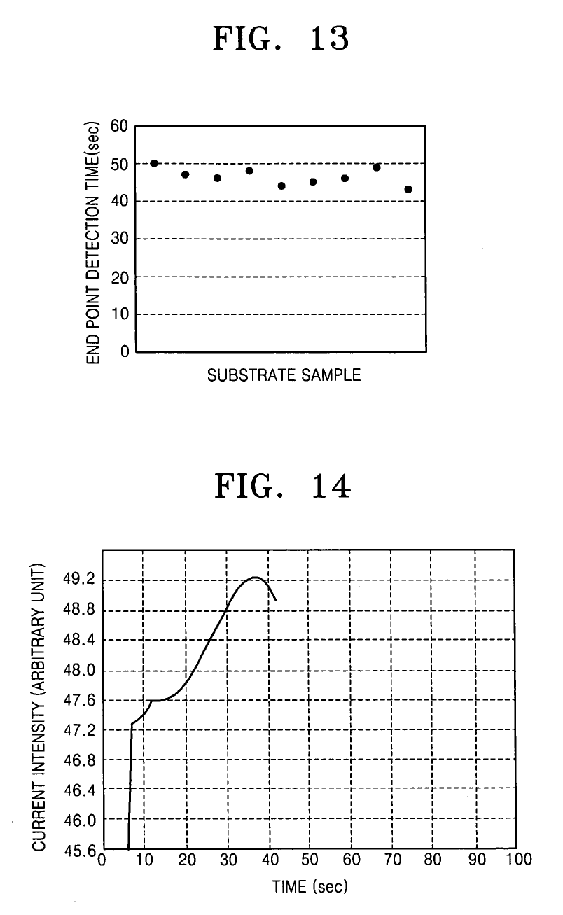

FIG. 13 illustrates a graph of end point detection time with respect to semiconductor substrates when the insulation films 54a and 54b on the semiconductor substrate are first polished as illustrated in FIG. 10. FIG. 14 illustrates a graph of a current intensity of a motor rotating the platen 30 with respect to time. This data is used to measure the end point detection time of FIG. 13.

Referring to FIG. 13, when the insulation films 54a and 54b with respect to various semiconductor substrates 100 are first polished, the end point detection times obtained by measuring the current intensity of the motor of rotating the platen 30 are consistently between about 40 to about 50 seconds. Referring to FIG. 14, the current intensity of the motor rotating the platen 30 also ends at about 48 seconds. Therefore, when the insulation films 54a and 54b are first polished, stable end point detection time can be obtained, thereby enabling the maintenance of the insulation films 54a and 54b at a predetermined height.

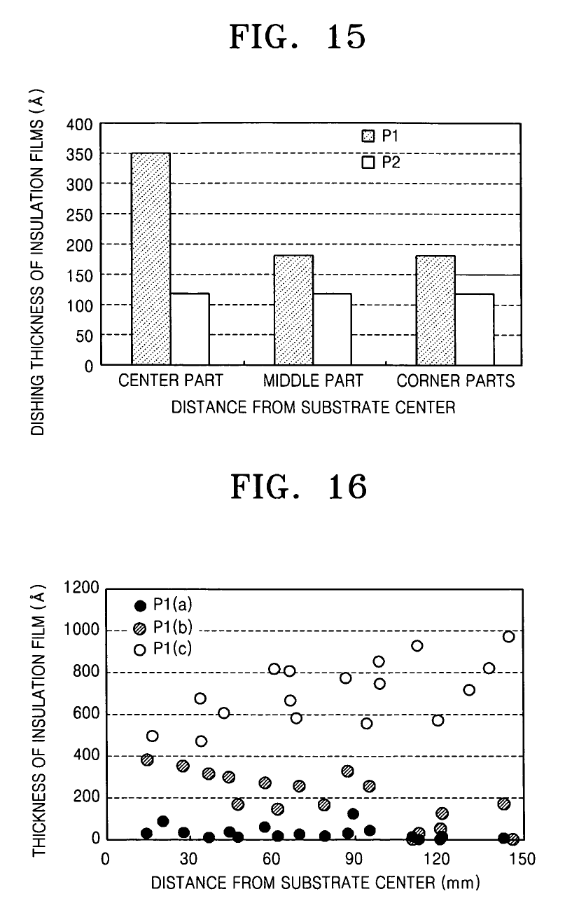

FIG. 15 illustrates a graph of the dishing thickness of the insulation films 54a and 54b when the insulation films 54a and 54b on the semiconductor substrate 100 are first and second polished as shown in FIGS. 10 and 11. Referring to FIG. 15, when the insulation films 54a and 54b on the semiconductor substrate 100 are first polished (P1) as shown in FIG. 10, the dishing thickness of the insulation films 54a and 54b that are sunken in is about 350 Å in the center part, and about 170 Å in the middle and corner parts. The center part is 9 mm away from the center of the semiconductor substrate 100, and the middle and corner parts are 61 mm and 140 mm from the center of the semiconductor substrate 100, respectively.

When the insulation films 54a and 54b on the semiconductor substrate 100 are second polished (P2) as shown in FIG. 11, the dishing thickness of the insulation films 54a and 54b that are sunken in is consistently about 100 Å to about 120 Å in the center part as well as in the middle and corner parts. Therefore, when the insulation films 54a and 54b are first and second polished, the dishing thickness can be controlled.

FIG. 16 illustrates a graph of the thickness distribution of the insulation films 54a and 54b on the polishing prevention film patterns 50a and 50b after the insulation films 54a and 54b on the semiconductor substrate 100 are first polished as shown in FIG. 10.

Referring to FIG. 16, P1(a) and P1(b) are obtained by depositing the insulation films 54a and 54b having the thickness of about 4,300 Å to about 4,800 Å, respectively, and first polishing the insulation films 54a and 54b as shown in FIG. 10 using a ceria slurry. P1(c) is obtained by first polishing the insulation films 54a and 54b using a silica slurry. In P1(c), the thickness distribution of the insulation films 54a and 54b on the polishing prevention film patterns 50a and 50b is about 500 Å to 1,000 Å and thus, the insulation films 54a and 54b are very thick.

In P1(a) and P1(b), the thickness distribution of the insulation films 54a and 54b on the polishing prevention film patterns 50a and 50b is below 400 Å, and thus, the insulation films 54a and 54b are very thin. Therefore, the thickness of the insulation films 54a and 54b can be greatly reduced in the first polishing using a ceria slurry, thereby increasing a process margin of the second polishing.

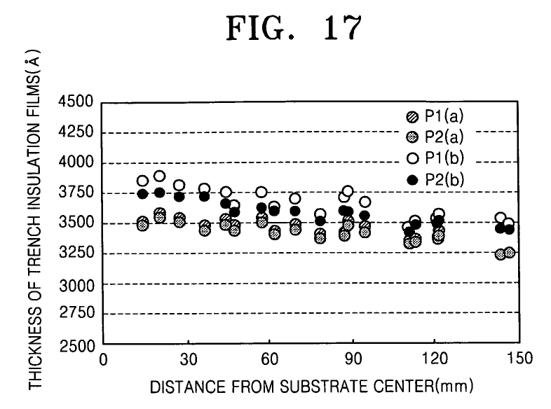

FIG. 17 illustrates a graph of the thickness distribution of the insulation films 54a and 54b that are buried in trenches when the insulation films 54a and 54b on the semiconductor substrate 100 undergo first and second polishing as shown in FIGS. 10 and 11. Referring to FIG. 17, P1(a) and P1(b) are obtained by depositing the insulation films 54a and 54b that are buried in trenches, having the thickness of about 4,300 Å to about 4,800 Å, respectively, and undergoing the first polishing. P2(a) and P2(b) are obtained by depositing the insulation films 54a and 54b that are buried in trenches, having the thickness of about 4,300 Å to about 4,800 Å, respectively, and undergoing second polishing. In P2(a), the carrier 36 applies a pressure of about 2 psi to the polishing pad 32 for about 60 seconds in the second polishing. In P2(b), the carrier 36 applies a pressure of about 2 psi to the polishing pad 32 for about 80 seconds in the second polishing. The thickness of the insulation films 54a and 54b that are buried in trenches from the center part of the semiconductor substrate 100 to the corners thereof remains constant.

The trench isolation method of a semiconductor device according to an embodiment may include a first polish of insulation films using a first polishing pad, using a slurry including an abrasive and having a polishing selection ratio with respect to polishing prevention film patterns. The abrasive may uses a ceria slurry in the first polishing. The insulation films, which are polished by using the polishing prevention film patterns as polishing prevention films, may be second polished using a second polishing pad including abrasive so that a trench isolation is completed. The abrasive may uses ceria in the second polishing. When the insulation films are first polished, an end point detection method may be used to detect polishing end point lines of the insulation films that are being polished.

An embodiment first polishes the insulation films using the first polishing pad, using the abrasive having the polishing selection ratio, and second polishes the insulation films using the second polishing pad including the abrasive, thereby increasing a polishing process margin and improving the reliability of semiconductor device.

Exemplary embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A trench isolation method of a semiconductor device, the method comprising:
forming polishing prevention film patterns on a semiconductor substrate;
etching the semiconductor device by using the polishing prevention film patterns as masks and forming trenches;
forming conformal insulation films on the semiconductor substrate and the polishing prevention film patterns by burying the trenches;
first polishing the conformal insulation films using a first polishing pad by using a slurry including an abrasive having a polishing selection ratio with respect to the polishing prevention film patterns; and
second polishing the first polished conformal insulation films using a second polishing pad including an abrasive and by using the polishing prevention film patterns as polishing prevention films.

2. The method as claimed in claim 1, wherein the polishing prevention film patterns are silicon nitride films or silicon oxide nitride films.

3. The method as claimed in claim 1, wherein the conformal insulation films are boronphosphosilicate glass (BPSG) films, phosphosilicate glass (PSG) films, high density plasma (HDP) oxide films, tetra ethyl ortho silicate (TEOS) films, undoped silica glass (USG) films or high aspect ratio process (HARP) films.

4. The method as claimed in claim 1, wherein a ceria slurry is used to first polish the conformal insulation films.

5. The method as claimed in claim 4, wherein the ceria slurry used to first polish the conformal insulation films has pH of about 5 to about 9.

6. The method as claimed in claim 4, wherein, before first polishing of the conformal insulation films using the ceria slurry, the conformal insulation films are preliminarily polished by the first polishing pad using a silica slurry.

7. The method as claimed in claim 1, wherein, when the conformal insulation films are first polished, an end point detection method is used to maintain a part of the conformal insulation films that has an original thickness on the polishing prevention film patterns.

8. The method as claimed in claim 1, wherein the abrasive used to second polish the conformal insulation films is ceria.

9. A trench isolation method of a semiconductor device, the method comprising:
forming polishing prevention film patterns on a semiconductor substrate;
etching the semiconductor device by using the polishing prevention film patterns as masks and forming trenches;
forming insulation films on the semiconductor substrate and the polishing prevention film patterns by burying the trenches, wherein the insulation films have a step between the surface of a part that is buried in the trenches and the surface of a part formed on the semiconductor substrate and the polishing prevention film patterns;
first polishing and planarizing the insulation films having the step using a first polishing pad, using a slurry including an abrasive having a polishing selection ratio with respect to the polishing prevention film patterns; and
second polishing the first polished insulation films using a second polishing pad including an abrasive and by using the polishing prevention film patterns as polishing prevention films.

10. The method as claimed in claim 9, wherein the trenches comprise a narrow first trench and a second trench that is wider than the first trench.

11. The method as claimed in claim 9, wherein the polishing prevention film patterns comprise a narrow first polishing prevention film pattern and a second polishing prevention film pattern that is wider than the first polishing prevention film pattern.

12. The method as claimed in claim 9, wherein the polishing prevention film patterns are silicon nitride films or silicon oxide nitride films, and the insulation films are boronphosphosilicate glass (BPSG) films, phosphosilicate glass (PSG) films, high density plasma (HDP) oxide films, tetra ethyl ortho silicate (TEOS) films, undoped silica glass (USG) films or high aspect ratio process (HARP) films.

13. The method as claimed in claim 9, wherein a ceria slurry is used to first polish the insulation films, and ceria is used to second polish the insulation films.

14. The method as claimed in claim 9, wherein, before first polishing of the insulation films using the ceria slurry, the insulation films are preliminarily polished using the first polishing pad by using a silica slurry.

15. The method as claimed in claim 9, wherein, when the insulation films are first polished, an end point detection method is used to maintain a part of the insulation films that has an original thickness on the polishing prevention film patterns.

16. A trench isolation method of a semiconductor device, the method comprising:
forming a first part including first polishing prevention film patterns having a high density and a second part including second polishing prevention film patterns having a density lower than that of the first polishing prevention film patterns on a semiconductor substrate;
forming a narrow first trench between the first polishing prevention film patterns on the semiconductor substrate;
forming a second trench that is wider than the first trench between the second polishing prevention film patterns on the semiconductor substrate;
forming insulation films having a step between the surface of a part that is buried in the second trench and the surface of a part formed on the semiconductor substrate, the first trench, and the first polishing prevention film pattern by burying the first and second trenches;
first polishing and planarizing the insulation films having the step using a first polishing pad using a slurry including an abrasive having a polishing selection ratio with respect to the first and second polishing prevention film patterns; and
second polishing the first polished insulation films using a second polishing pad including an abrasive and by using the first and second polishing prevention film patterns as polishing prevention films.

17. The method as claimed in claim 16, wherein, when the insulation films are first polished, an end point detection method is used to maintain a part of the insulation films that has an original thickness on the first polishing prevention film pattern.

18. The method as claimed in claim 16, wherein the first and second trenches are formed by etching the semiconductor substrate by using the first and second polishing prevention film patterns, respectively, as masks.

19. The method as claimed in claim 16, wherein the first and second polishing prevention film patterns are silicon nitride films or silicon oxide nitride films, and the insulation films are boronphosphosilicate glass (BPSG) films, phosphosilicate glass (PSG) films, high density plasma (HDP) oxide films, tetra ethyl ortho silicate (TEOS) films, undoped silica glass (USG) films or high aspect ratio process (HARP) films, and a ceria slurry is used to first polish the insulation films, and ceria is used to second polish the insulation films.

20. The method as claimed in claim 19, wherein, before first polishing of the insulation films using the ceria slurry, the insulation films are preliminarily polished using the first polishing pad by using a silica slurry.
